(19) United States
(12) Patent Application Publication
(10) Pub. No.: US 2010/0294649 A1
(43) Pub. Date: Nov. 25, 2010

(54) SPUTTERING FILM FORMING METHOD AND SPUTTERING FILM FORMING APPARATUS

(75) Inventors: Hajime Nakamura, Chigasaki-shi (JP); Takaaki Shindou, Chigasaki-shi (JP); Mayako Matsuda, Chigasaki-shi (JP); Koji Ishino, Chigasaki-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/811,475

(22) PCT Filed: Jan. 21, 2009
(86) PCT No.: PCT/JP2009/050843

§ 371 Date: Aug. 5, 2010

(30) Foreign Application Priority Data
Jan. 21, 2008 (JP) 2008-010336

(51) Int. Cl. C23C 14/34

(52) U.S. Cl. 204/192.12; 204/298.16

(57) ABSTRACT

In a sputtering film forming method of the invention, a magnetron cathode with a magnet arranged on a back surface side of a target is used, a substrate is transported in a first direction on a front surface side of the target, and the magnet is moved in reciprocating motion in the first direction and a second direction which is opposite to the first direction, thereby performing sputtering film formation on the substrate. Sputtering film formation is performed where a speed of the movement of the magnet in the first direction and a speed of the movement of the magnet in the second direction are different from each other.

### TECHNICAL FIELD

The present invention relates to a sputtering film forming method and a sputtering film forming apparatus.

Priority is claimed on Japanese Patent Application No. 2008-010336, filed Jan. 21, 2008, the contents of which are incorporated herein by reference.

### BACKGROUND ART

Conventionally, in those cases where a thin film is to be formed on a substrate by means of a sputtering method, a sputtering film forming apparatus that has a high deposition speed and superior productivity and uses a magnetron cathode is widely used.

In this sputtering film forming apparatus, in general, a plurality of magnetron cathodes are arranged within a sputtering chamber along the substrate transporting direction. Moreover the substrate is transported so as to face the target of the magnetron cathodes, and thereby a thin film is formed on the substrate surface.

Here, there is a commonly known a method in which a magnet is arranged on the back surface of the target, and film formation is performed while the magnet is moved in order to improve utilization efficiency of the target. If film formation is performed on the substrate while moving the magnet in this manner, then there will be formed a portion having a thick film thickness and a portion with a thin film thickness. As a result, there is a problem in that the film characteristic is reduced. Specifically, in a case where the magnet is moved in the same direction as that of substrate transportation, the relative speed between them becomes low, and consequently a portion with a thick film thickness is formed. In contrast, in a case where the magnet is moved in the direction opposite to that of substrate transportation, the relative speed between them becomes high, and consequently a portion with a thin film thickness is formed.

In order to solve this problem, there has been proposed a sputtering film forming apparatus configured such that the phase determined by each of the plurality of magnetron cathodes satisfies a predetermined phase relationship (for example, refer to Patent Document 1).

[Patent Document 1] Japanese Unexamined Patent Application, First Publication No. H11-246969

### DISCLOSURE OF INVENTION

### [Problems to be Solved by the Invention]

However, in the sputtering apparatus of Patent Document 1, it is assumed that film formation is to be performed while the magnet is moved at a constant speed. With such a configuration, since the relative speed between the magnet and the substrate is different depending on the direction of the movement of the magnet, the films will not be formed axisymmetrically. Specifically, as shown in FIG. 10, if the speed of the movement of the magnet is set at a same reciprocating speed on the approach route and the return route, then the distance d3 of the thick film portion will become short in a case where the magnet is moved in the same direction as that of the substrate and the relative speed therebetween becomes low. In contrast, in a case where the magnet is moved in the direction opposite to that of the substrate and the relative speed therebetween becomes high, the distance d4 of the thin film portion becomes long. FIG. 10 will be described in detail later.

Therefore, as shown in FIG. 11, even if the phase of the thin film shape formed by the respective magnetron cathodes is shifted by a half cycle to perform film formation with use of two units of the magnetron cathode, while variation in the film thickness is improved compared to the case of using one unit of the magnetron cathode, it is difficult to obtain a uniform film thickness (refer to the alternate long and short dash line in FIG. 11; to be described in detail later).

Consequently, the present invention takes into consideration the above circumstances, with an object of providing a sputtering film forming method and a sputtering film forming apparatus capable of making film thickness uniform at a higher level of precision.

### [Means for Solving the Problem]

In order to solve the above problems and achieve the above object, the present invention employs the followings.

(1) A sputtering film forming method of the present invention uses a magnetron cathode with a magnet arranged on a back surface side of a target. A substrate is transported in a first direction on a front surface side of the target. The magnet is moved in reciprocating motion in the first direction and a second direction which is opposite to the first direction, thereby performing sputtering film formation on the substrate. Sputtering film formation is performed where a speed of the movement of the magnet in the first direction and a speed of the movement of the magnet in the second direction are different from each other.

According to the sputtering film forming method according to (1) above, the relative speed between the magnet and the substrate can be adjusted in cases where the magnet is moved in the first direction and where the magnet is moved in the second direction. Accordingly, the thin film shape to be formed on the substrate can be controlled. Therefore, the film thickness can be made uniform at a higher level of precision.

(2) The sputtering film forming method of (1) above may be performed such that: in a case where two units of the magnetron cathode are arranged along the first direction and sputtering film formation is performed on the substrate individually using the respective magnetron cathodes, the speed of the movement of the respective magnets in the first direction and the speed of the movement of the respective magnets in the second direction are adjusted so that a film thickness deviation in the first direction in a region where the film thickness becomes thicker than an average value, and the film thickness deviation in the first direction in a region where the film thickness becomes thinner than the average value, have the same level of amplitude while the polarities thereof are opposite; a phase of reciprocating movement of the respective magnets is adjusted so that a phase of the film thickness variation in the first direction of a thin film to be formed on the substrate by the respective magnetron cathodes is respectively shifted by a half cycle; and the respective magnetron cathodes are used at the same time, to thereby perform sputtering film formation.

In the case of (2) above, by superimposing the thin film shape formed on the substrate by each of the two units of the magnetron cathode, the film thickness of the thin film formed on the substrate can be made substantially uniform along the transportation direction thereof (the first direction).

(3) The sputtering film forming method of (1) above may be performed such that: in a case where three units of the magnetron cathode are arranged along the first direction and sputtering film formation is performed on the substrate individually using the respective magnetron cathodes so as to form a thin film with a film thickness that changes in a rectangular wave form shape, the speed of the movement of the respective magnets in the first direction and the speed of the movement of the respective magnets in the second direction are adjusted so that a ratio of a length in the first direction in a portion where the film thickness is the thickest and a length in the first direction in a portion where the film thickness is the thinnest is 1:2 or 2:1; a phase of reciprocating movement of the respective magnets is adjusted so that the phase of film thickness variation in the first direction of a thin film to be formed on the substrate by the respective magnetron cathodes is respectively shifted by a ⅓ cycle; and the respective magnetron cathodes are used at the same time, to thereby perform sputtering film formation.

In the case of (3) above, in a case where the thin film shape becomes a rectangular wave form shape when the film formation is performed on the substrate with use of one unit of a magnetron cathode, by superimposing the thin film shape formed on the substrate by each of the three units of the magnetron cathode, the film thickness of the thin film formed on the substrate can be made substantially uniform along the transportation direction thereof (the first direction).

(4) The sputtering film forming method of (1) above may be performed such that: in a case where three units of the magnetron cathode are arranged along the first direction and sputtering film formation is performed on the substrate individually using the respective magnetron cathodes so as to form a thin film with a film thickness that changes in a sine wave form shape, the speed of the movement of the respective magnets in the first direction and the speed of the movement of the respective magnets in the second direction are adjusted so that a film thickness deviation in the first direction in a region where the film thickness becomes thicker than the average value and a film thickness deviation in the first direction in a region where the film thickness becomes thinner than the average value, have the same level of amplitude while the polarities thereof are opposite; a phase of reciprocating movement of the respective magnets is adjusted so that the phase of film thickness variation in the first direction of a thin film to be formed on the substrate by the respective magnetron cathodes is respectively shifted by a ⅓ cycle; and the respective magnetron cathodes are used at the same time, to thereby perform sputtering film formation.

In the case of (4) above, in a case where the thin film shape becomes a sine wave form shape when the film formation is performed on the substrate with use of one unit of a magnetron cathode, by superimposing the thin film shape formed on the substrate by each of the three units of the magnetron cathode, the film thickness of the thin film formed on the substrate can be made substantially uniform along the transportation direction thereof (the first direction).

(5) Four or more units of the magnetron cathode arranged along the first direction are divided into a first aggregate that includes two units of the magnetron cathode and a second aggregate that includes three units of the magnetron cathode, and sputtering film formation may be performed with the first aggregate in the sputtering film forming method according to (2) above, and sputtering film formation may be performed with the second aggregate in the sputtering film forming method according to either one of (3) and (4) above.

In the case of (5) above, in a case where four or more units of the magnetron cathode are provided inside an apparatus, if these magnetron cathodes are divided into a two-unit aggregate and a three-unit aggregate, the film thickness of a thin film to be formed on a substrate in each of the aggregates can be made substantially uniform along the transportation direction (the first direction) thereof, and eventually the thickness of the film formed on the substrate can be made substantially uniform.

(6) A sputtering film forming apparatus of the present invention is a sputtering film forming apparatus that is provided with a target arranged within a sputtering chamber and a magnet arranged on a back surface side of this target, in which a substrate is transported in a first direction on a front surface side of the target, and the magnet is moved in reciprocating motion in the first direction and a second direction which is opposite to the first direction, thereby performing sputtering film formation on the substrate, wherein a speed of the movement of the magnet in the first direction and a speed of the movement of the magnet in the second direction are set at different speeds.

According to the sputtering film forming apparatus according to (6) above, the relative speed between the magnet and the substrate can be adjusted in cases where the magnet is moved in the first direction and where the magnet is moved in the second direction. Accordingly, the thin film shape to be formed on the substrate can be controlled. Therefore, the film thickness can be made uniform at a higher level of precision.

### [Effect of the Invention]

According to the sputtering film forming method according to (1) above, the relative speed between the magnet and the substrate can be adjusted in cases where the magnet is moved in the first direction and where the magnet is moved in the second direction. Accordingly, the thin film shape to be formed on the substrate can be controlled. Therefore, the film thickness can be made uniform at a higher level of precision.

### BRIEF DESCRIPTION OF THE DRAWINGS

FIG. 1 is a schematic configuration diagram (plan view) showing relevant parts of a sputtering film forming apparatus in a first embodiment of the present invention.

FIG. 2 shows a thin film shape in a case where film formation is conducted using one unit of a magnetron cathode in the same embodiment.

FIG. 3 shows a thin film shape in a case where film formation is conducted using two units of a magnetron cathode in the same embodiment.

FIG. 4 shows a thin film shape in a case where film formation is conducted in another mode using one unit of a magnetron cathode in the same embodiment.

FIG. 5 shows a thin film shape in a case where film formation is conducted in another mode using two units of a magnetron cathode in the same embodiment.

FIG. 6 is a schematic configuration diagram (plan view) showing relevant parts of a sputtering film forming apparatus in a second embodiment of the present invention.

FIG. 7 shows a thin film shape in a case where film formation is conducted using one unit of a magnetron cathode in the same embodiment.

FIG. 8 shows a thin film shape in a case where film formation is conducted using three units of a magnetron cathode in the same embodiment.

FIG. 9 shows a thin film shape in a case where film formation is conducted using three units of a magnetron cathode in a third embodiment.

FIG. 10 shows a thin film shape in a case where film formation is conducted using one unit of a magnetron cathode and the film formation is conducted with a conventional method.

FIG. 11 shows a thin film shape in a case where film formation is conducted using two units of a magnetron cathode and the film formation is conducted with a conventional method.

FIG. 12 shows a thin film shape in a case where film formation is conducted using three units of a magnetron cathode under the conditions in the first embodiment.

FIG. 13 shows a thin film shape in a case where film formation is conducted in another mode using one unit of a magnetron cathode and the film formation is conducted with a conventional method.

FIG. 14 shows a thin film shape in a case where film formation is conducted in another mode using two units of a magnetron cathode and the film formation is conducted with the conventional method.

### BRIEF DESCRIPTION OF THE REFERENCE SYMBOLS

10, 110 Sputtering film forming apparatus
13 Sputtering chamber
15, 115 Magnetron cathode
17 Target
21 Substrate
29 Permanent magnet (magnet)

### BEST MODE FOR CARRYING OUT THE INVENTION

### First Embodiment

### (Sputtering Film Forming Apparatus)

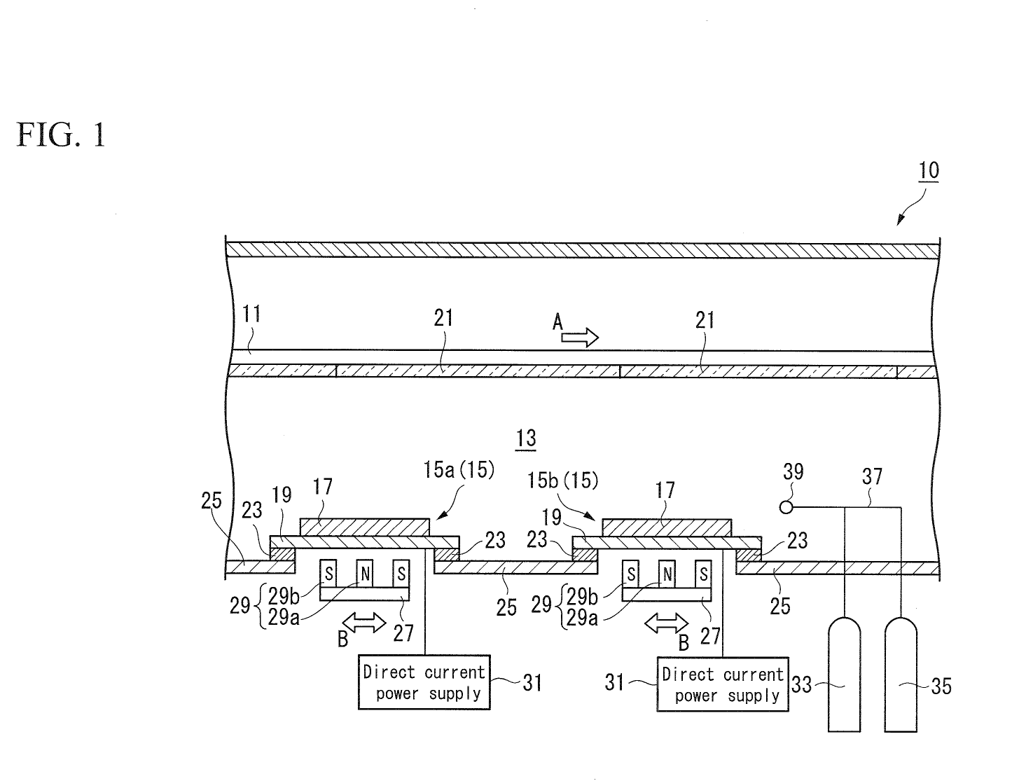

A sputtering film forming apparatus according to a first embodiment of the present invention is described, with reference to FIG. 1 to FIG. 5.

FIG. 1 is a schematic configuration diagram (plan view) showing the relevant parts of the sputtering film forming apparatus. As shown in FIG. 1, a sputtering film forming apparatus 10 is an in-line type sputtering apparatus for mass production. In this sputtering film forming apparatus 10, substrates 21 are loaded on a carrier 11 that is driven at a constant speed, and these substrates 21 are continuously and sequentially transported within a sputtering chamber 13 in a direction of arrow A (first direction). As the method of transporting the carrier 11 (substrates 21), there may be used transporting methods such as a transporting roller connected to a motor and a rack-pinion mechanism. Moreover, the substrate 21 may be transported by clipping the upper end edge and lower end edge of the substrate 21 using grooved rollers and rotating the grooved rollers with a motor or the like.

Magnetron cathodes 15 are arranged in positions facing the substrate 21. In the present embodiment, there are arranged two units of the magnetron cathode 15, where one which the substrate 21 passes first is a magnetron cathode 15a and the other one which the substrate 21 passes next is a magnetron cathode 15b.

A target 17 is arranged on the surface of the magnetron cathode 15 facing the substrate 21. The target 17 is metal-bonded to a backing plate 19, and is attached on a wall surface 25 of the sputtering chamber 13 via an insulating plate 23.

On the back surface side of the backing plate 19, there is provided a permanent magnet 29 that is adhered on a magnet yoke 27. This permanent magnet 29, with use of a moving device (not shown in the diagram) composed of a motor for example, is capable of one-dimensional motion in the front-rear direction along the direction of transporting the substrate 21 as shown with arrow B. Here, this permanent magnet 29 is configured so that it can be moved by the moving device, and the speed of the movement thereof can be set at different speeds for the direction along the direction of transporting the substrate 21 (first direction) and for the opposite direction (second direction). The permanent magnet 29 comprises a center magnet 29a and peripheral magnets 29b that surround this center magnet 29a, respectively having repulsive magnetic poles. Moreover, the permanent magnet 29 may be capable of two-dimensional motion within a plane that is parallel with the substrate 21.

On the backing plate 19, there is provided a direct current power supply 31 that applies a direct current field to the target 17.

In the sputtering film forming apparatus 10, there are arranged a first gas cylinder 33 having a sputtering gas to be supplied into the sputtering chamber 13 enclosed therein, and a second gas cylinder 35 having a reactive gas to be supplied into the sputtering chamber 13 enclosed therein. The first gas cylinder 33 and the second gas cylinder 35 are communicated with the interior of the sputtering chamber 13 via pipework 37. The end of the pipework 37 is connected to a gas induction nozzle 39, thereby allowing the gasses injection to be made into the sputtering chamber 13.

### (Effect)

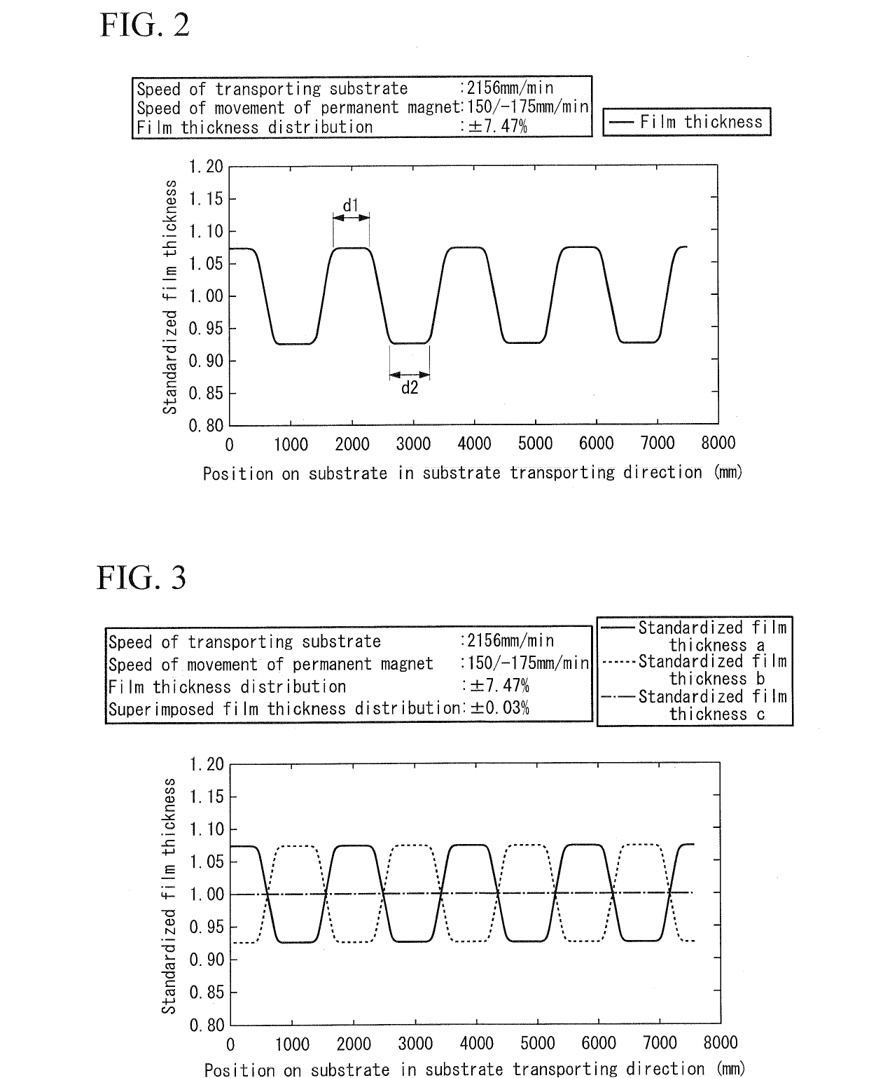

Next, there is described, with reference to FIG. 2 and FIG. 3, a procedure in a case where film formation is performed on the substrate 21 using the above-mentioned sputtering film forming apparatus 10. First, the direct current power supply 31 is activated so as to apply a direct current field to the target 17 via the backing plate 19. Consequently, the permanent magnet 29 (the center magnet 29a and the peripheral magnets 29b) of the magnetron cathode 15 forms a closed-loop magnetic field on the surface of the target 17. This magnetic field confines electrons therein so that highly dense plasma is generated in this portion, and thereby a high deposition speed sputtering is performed.

Here, in the in-line type sputtering film forming apparatus 10, film formation is performed while the substrates 21 on the carrier 11 are continuously moved. Therefore, if film formation is performed while the speed of the movement of the permanent magnet 29 is maintained at a constant speed (the movement speed thereof in the same direction as the direction of transporting the substrate and the movement speed thereof in the opposite direction are set at the same speed), plasma concentrates on the target 17 according to the direction of the movement of the permanent magnet 29, and consequently the relative speed of the movement of the substrate 21 with respect to the portion where sputtering is occurring is different. For example, in a case where film formation is performed on the substrate 21 by means of sputtering film forming with use of one unit of the magnetron cathode 15, the speed of transporting the substrate 21 is set at 2156 mm/minute, and the movement speed of the permanent magnet 29 both in the same direction as the direction of transporting the substrate 21 and in the opposite direction is set at 150 mm/minute. If the film formation is performed under such conditions, a thin film (film thickness distribution is ±6.94%) having the shape illustrated with the solid line in FIG. 10 in the thickness direction, is formed on the substrate 21. The horizontal axis in FIG. 10 represents positions on the substrate in the substrate transporting direction, and the vertical axis represents standardized film thicknesses (where the intermediate value or average value of the maximum value and minimum value of the film thickness is 1.0). Moreover, in the present embodiment, the film thickness distribution is found as follows.

Film thickness distribution=(maximum value of film thickness−minimum value of film thickness)/(maximum value of film thickness+minimum value of film thickness)×100 (%)

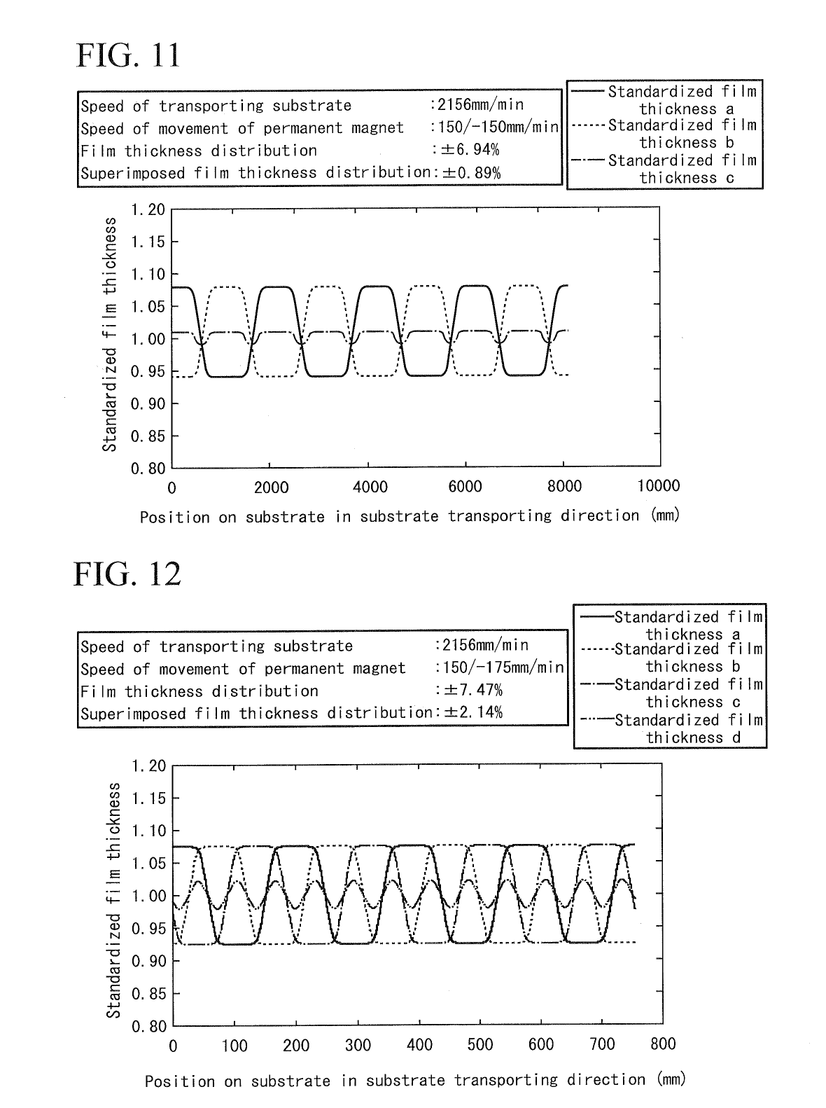

At this time, the width d3 of a portion having a thick film thickness and the width d4 of a portion having a thin film thickness in the substrate transporting direction are different, and d3<d4. Therefore, by using two units of the magnetron cathodes 15a and 15b and shifting the phase of the magnetron cathodes 15a and 15b so that the thin film shape formed by the respective magnetron cathodes 15a and 15b is respectively shifted by a half cycle, a thin film having a shape shown in FIG. 11 in the thickness direction (superimposed film thickness distribution is ±0.89%) is formed on the substrate 21. In FIG. 11, the solid line represents standardized film thickness of the thin film shape formed on the substrate 21 by one of the magnetron cathodes (for example, 15a). In FIG. 11, the dashed line represents standardized film thickness b of the thin film shape formed on the substrate 21 by the other magnetron cathode (for example, 15b). In FIG. 11, the alternate long and short dash line represents standardized film thickness c, which is an average value (the resultant value of dividing by 2) of a combined value of the solid line and dashed line. That is to say, with use of two units of the magnetron cathodes 15a and 15b, a thin film having a standardized film thickness c in the thickness direction is formed on the substrate 21. At this time, the film thickness distribution is improved compared to the case of conducting film formation with use of only one unit of the magnetron cathode 15, however, the film thickness distribution still cannot be made substantially uniform as a result.

Accordingly, if the permanent magnet 29 is simply moved at a constant speed with respect to the target 17, then in the thin film shape formed with use of one unit of the magnetron cathode 15, the width d3 of the portion having a thick film thickness and the width d4 of the portion having a thin film thickness are different, and consequently a uniform film thickness cannot be formed on the substrate 21.

In contrast, in the present embodiment, the speed of transporting the substrate 21 is set at 2156 mm/minute. The speed of the movement of the permanent magnet 29 in the same direction as the direction of transporting the substrate 21 is set at 150 mm/minute, and the speed of the movement thereof in the direction opposite to the direction of transporting the substrate 21 is set at 175 mm/minute. As a sputtering gas, an Ar gas is introduced into the sputtering chamber 13, and a small amount of oxygen gas is introduced as a reactive gas.

If film formation is conducted on the substrate 21 by means of sputtering film forming with use of one unit of the magnetron cathode 15 under such conditions, a thin film having the shape illustrated with the solid line in FIG. 2 in the thickness direction (film thickness distribution is ±7.47%) is formed on the substrate 21, in the direction of transporting the substrate 21. At this time, the width dl of the portion having a thick film thickness and the width d2 of the portion having a thin film thickness become substantially the same. That is to say, the distribution of the film thickness variation amount from the intermediate value in the substrate transporting direction in the region where the film thickness becomes thicker than the intermediate value, and the distribution of the film thickness variation amount from the intermediate value in the substrate transporting direction in the region where the film thickness becomes thinner than the intermediate value, have the same level of amplitude while the polarities thereof are opposite.

Here, the width d1 of the portion having the thick film thickness and the width d2 of the portion having the thin film thickness are found as specific numeric values.

When the amount of the movement of the permanent magnet 29 is X (mm), the amount of time in which the permanent magnet 29 is moving in the direction of transporting the substrate 21 is X/150 (minutes). At the same time, the amount of time in which the permanent magnet 29 is moving in the direction opposite to the direction of transporting the substrate 21 is X/175 (minutes).

The distances that the substrate is moving with respect to the magnet in these respective amounts of time are respectively d3 and d4, that is, the distance (length) that the film thickness is formed thick and the length that the film thickness is formed thin.

Here, the specific numeric values of d1 and d2 are calculated as follows.

d1=(2156 (mm/minute)−150 (mm/minute))×X/150 (minute)≈13.37 X (mm)

d2=(2156 (mm/minute)+175 (mm/minute))×X/175 (minute)≈13.32 X (mm)

Thus, as described above, the width dl of the portion having the thick film thickness and the width d2 of the portion having the thin film thickness become substantially the same.

When determining the speed of the movement of the permanent magnet 29 so that d1 and d2 become substantially the same, the speed of the movement is, for example, calculated as follows.

If the speed of transporting the substrate 21 is a (mm/minute), the speed of the movement of the permanent magnet 29 in the same direction as the direction of transporting the substrate 21 is 13 (mm/minute), the speed of the movement of the permanent magnet 29 in the direction opposite to the direction of transporting the substrate 21 is γ (mm/minute), and the amount of the movement of the permanent magnet 29 is X (mm), if d1 and d2 are substantially the same, then d1≈d2, resulting in:

(α−β)×X/β≈(α+γ)×X/γ

Rearrangement of this equation to solve for ₇ will give:

γ=αβ/(α−2β)

Therefore, if the speed a of transporting the substrate 21 and the speed β of the movement of the permanent magnet 29 in the same direction as the direction of transporting the substrate 21 are determined, γ that satisfies d1≈d2 can be found.

Therefore, as shown in FIG. 3, by using two units of the magnetron cathodes 15a and 15b and adjusting the phases so that the thin film shape formed by the respective magnetron cathodes 15a and 15b is respectively shifted by a half cycle, a thin film having a standardized film thickness a is formed on the substrate 21 by the one magnetron cathode 15a, and a thin film having a standardized film thickness b is formed on the substrate 21 by the other magnetron cathode 15b. That is to say, with use of two units of the magnetron cathodes 15a and 15b, a thin film having a standardized film thickness c in the thickness direction (superimposed film thickness distribution is ±0.03%) is formed on the substrate 21, and the film thickness can be made substantially uniform.

According to the present embodiment, in the sputtering film forming method in which a thin film is continuously formed on the substrate 21 being transported along the position facing the target 17 arranged within the sputtering chamber 13, by moving the permanent magnet 29 provided on the back surface of the target 17 in reciprocating motion along the direction parallel with the direction of transporting the substrate 21, the permanent magnet 29 is moved at different speeds when it is moved in the direction of transporting the substrate 21 and when it is moved in the opposite direction thereof.

Therefore, the relative speed between the permanent magnet 29 and the substrate 21 can be adjusted in cases where the permanent magnet 29 is moved in the same direction as the direction of transporting the substrate 21 and where it is moved in the opposite direction thereof. Consequently, the thin film shape to be formed on the substrate 21 can be controlled. Therefore, the film thickness can be made uniform at a higher level of precision.

Moreover, within the sputtering chamber 13, two units of the magnetron cathode 15 respectively comprising the target 17 and the permanent magnet 29 are arranged along the direction of transporting the substrate 21. At this time, in a case where each of the magnetron cathodes 15a and 15b individually performs film formation, the speed of the reciprocating movement of each of the permanent magnets 29 is adjusted so that the film thickness deviation in the substrate transporting direction in a region where the film thickness becomes thicker than the average value, and the film thickness deviation in the substrate transporting direction in a region where the film thickness becomes thinner than the average value, have the same level of amplitude while the polarities thereof are opposite. Furthermore, the phases of the reciprocating movement of each of the permanent magnets 29 are adjusted so that the phases of the film thickness variation in the substrate transporting direction of the thin film to be formed on the substrate 21 by the respective magnetron cathodes 15a and 15b are respectively shifted by a half cycle.

Therefore, by superimposing the thin film shape formed on the substrate 21 with one of the magnetron cathodes 15a and the thin film shape formed with the other magnetron cathode 15b, the film thickness of the thin film formed on the substrate 21 can be made substantially uniform along the transporting direction thereof.

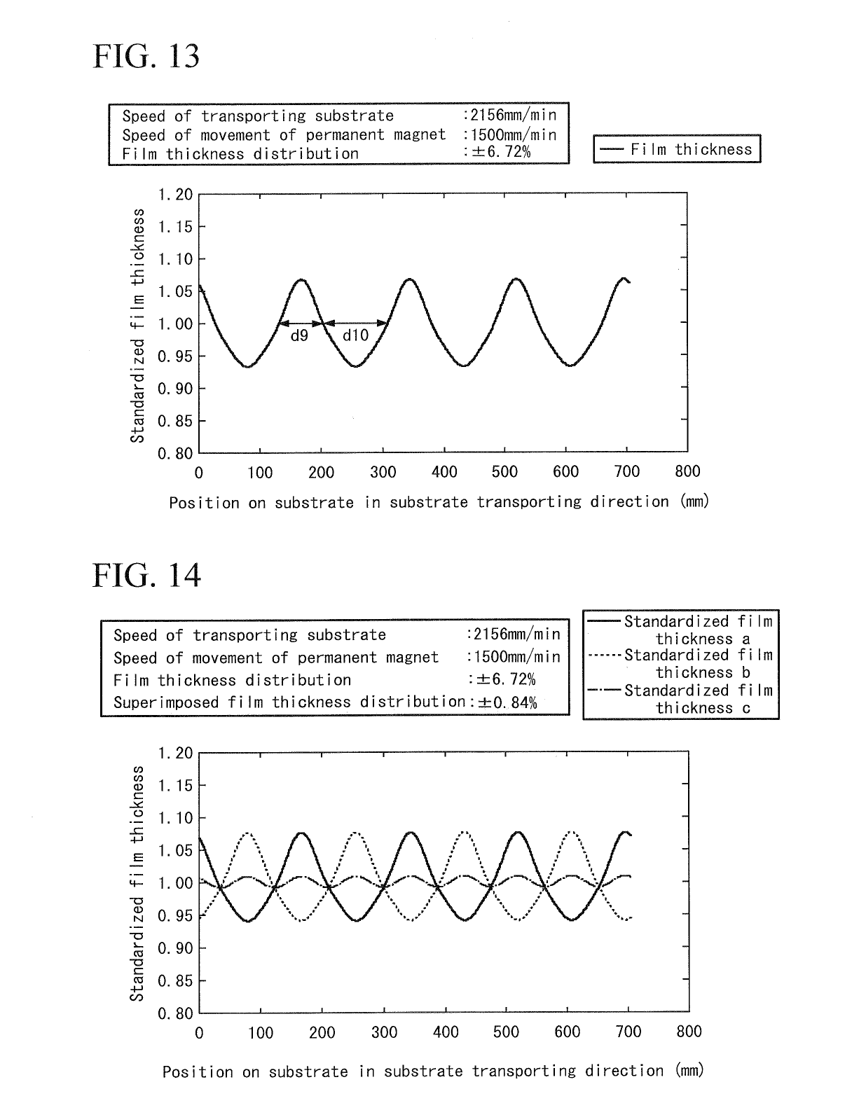

In a case where the speed of the movement of the permanent magnet 29 significantly differs from the speed of transporting the substrate 21, the thin film is formed in the rectangular wave form shape described above. However, if the speed of the movement of the permanent magnet 29 is brought close to the speed of transporting the substrate 21, the thin film is formed in a sine wave form shape. Also in this case, as observed conventionally, if the permanent magnet 29 is moved in reciprocating motion at a constant movement speed, the thin film shape to be formed on the substrate 21 will not be a rigorous sine wave form shape. For example, in a case where film formation is performed on the substrate 21 by means of sputtering film forming with use of one unit of the magnetron cathode 15, the speed of transporting the substrate 21 is set at 2156 mm/minute, and the movement speed of the permanent magnet 29 both in the same direction as the direction of transporting the substrate 21 and in the opposite direction is set at 1500 mm/minute. If the film formation is performed under such conditions, a thin film (film thickness distribution is ±6.72%) having a shape illustrated in FIG. 13 in the thickness direction, is formed on the substrate 21.

That is to say, the width d9 in the substrate transporting direction of the portion having a thickness thicker than the average value, and the width d10 in the substrate transporting direction of the portion having a film thickness thinner than the average value, do not become the same width.

Therefore, as shown in FIG. 14, even if the film formation is conducted by using two units of the magnetron cathodes 15a and 15b under these conditions and respectively shifting, by a half cycle, the thin film shape formed with use of each of the magnetron cathodes 15a and 15b, a thin film having a standardized film thickness c in the thickness direction (superimposed film thickness distribution is ±0.84%) is formed on the substrate 21, and the film thickness in the substrate transporting direction can not be made substantially uniform.

Consequently, as another mode of the present embodiment, the speed of transporting the substrate 21 is set at 2156 mm/minute. The speed of the movement of the permanent magnet 29 in the same direction as the direction of transporting the substrate 21 is set at 1500 mm/minute, and the speed of the movement thereof in the direction opposite to the direction of transporting the substrate 21 is set at 2500 mm/minute. As a sputtering gas, an Ar gas is introduced into the sputtering chamber 13, and a small amount of oxygen gas is introduced as a reactive gas.

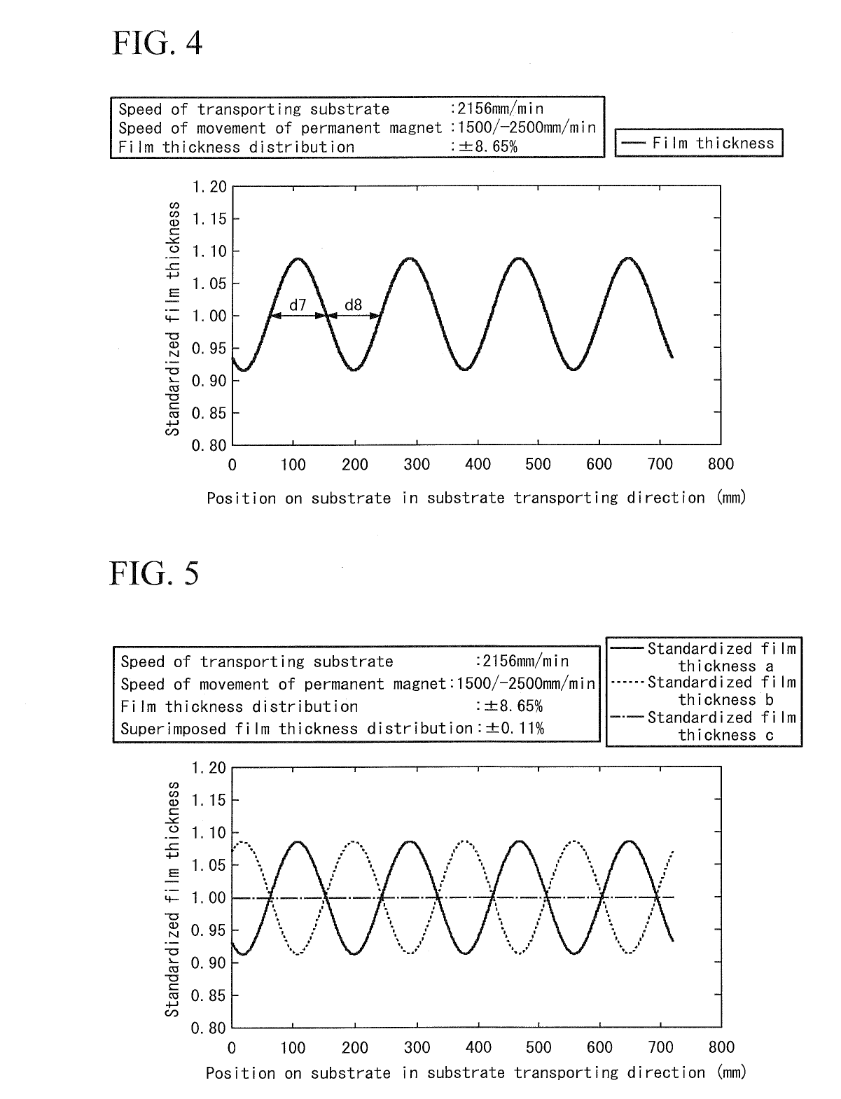

If film formation is conducted on the substrate 21 by means of sputtering film forming with use of one unit of the magnetron cathode 15 under such conditions, a thin film having a sine wave form shape (round wave form) illustrated with the solid line in FIG. 4 in the thickness direction (film thickness distribution is ±8.65%) is formed on the substrate 21, in the direction of transporting the substrate 21. It can be understood that the film thickness deviation in the substrate transporting direction in a region where the film thickness becomes thicker than the average value, and the film thickness deviation in the substrate transporting direction in a region where the film thickness becomes thinner than the average value, have the same level of amplitude while the polarities thereof are opposite. That is to say, the width d7 in the substrate transporting direction of the portion having a film thickness thicker than the average value, and the width d8 in the substrate transporting direction of the portion having a thin film thickness, become substantially the same.

Therefore, as shown in FIG. 5, by using two units of the magnetron cathode 15 and adjusting the phases so that the thin film shape formed by the respective magnetron cathodes 15a and 15b is respectively shifted by a half cycle, a thin film having a standardized film thickness a is formed on the substrate 21 by the one magnetron cathode 15a, and a thin film having a standardized film thickness b is formed on the substrate 21 by the other magnetron cathode 15b. That is to say, with use of two units of the magnetron cathodes 15a and 15b, a thin film having a standardized film thickness c in the thickness direction (superimposed film thickness distribution is ±0.11%) is formed on the substrate 21, and the film thickness can be made substantially uniform.

### Second Embodiment

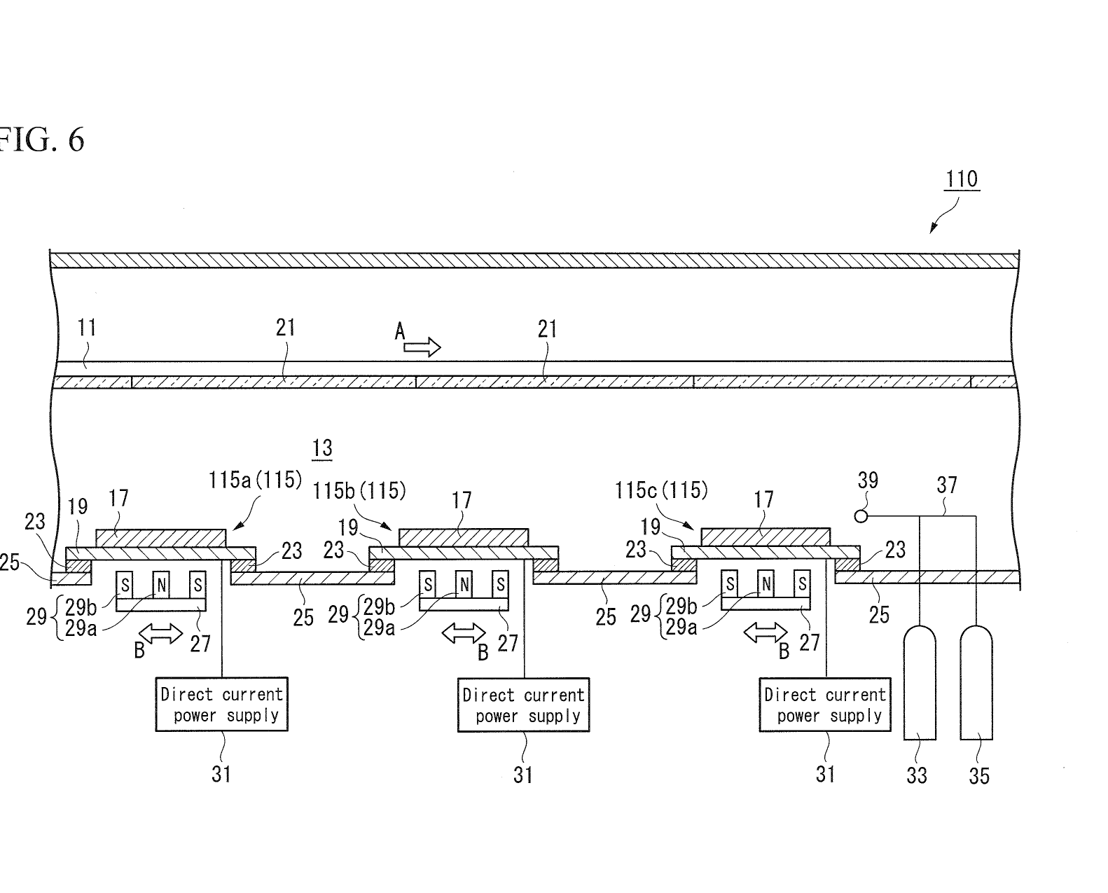

Next, a second embodiment of the present invention is described, with reference to FIG. 6 to FIG. 8.

The present embodiment only differs from the first embodiment in the arrangement configuration of the magnetron cathode while other configurations thereof are substantially the same as those in the first embodiment, and accordingly the same reference symbols are given to the same portions and detailed descriptions thereof are omitted.

FIG. 6 is a schematic configuration diagram (plan view) showing the relevant parts of a sputtering film forming apparatus. As shown in FIG. 6, a sputtering film forming apparatus 110 includes three units of the magnetron cathode 115 arranged therein. The magnetron cathodes 115 are such that one which the substrate 21 passes first is a first magnetron cathode 115a, one which the substrate 21 passes second is a second magnetron cathode 115b, and one which the substrate 21 passes third is a third magnetron cathode 115c.

Here, FIG. 12 shows the results of the case where the speed of transporting the substrate 21 and the speed of the movement of the permanent magnet 29 are set to the same values as those in the first embodiment so that the phase of the thin film shape formed using the respective magnetron cathodes 115a to 115c is respectively shifted by a ⅓ cycle. As shown in FIG. 12, even if three units of the magnetron cathode are shifted by a ⅓ cycle, the film thickness does not become substantially uniform (superimposed film thickness distribution is ±2.14%).

Consequently, in the present embodiment, the speed of transporting the substrate 21 is set at 2156 mm/minute. The speed of the movement of the permanent magnet 29 in the same direction as the direction of transporting the substrate 21 is set at 250 mm/minute, and the speed of the movement thereof in the direction opposite to the direction of transporting the substrate 21 is set at 150 mm/minute. As a sputtering gas, an Ar gas is introduced into the sputtering chamber 13, and a small amount of oxygen gas is introduced as a reactive gas.

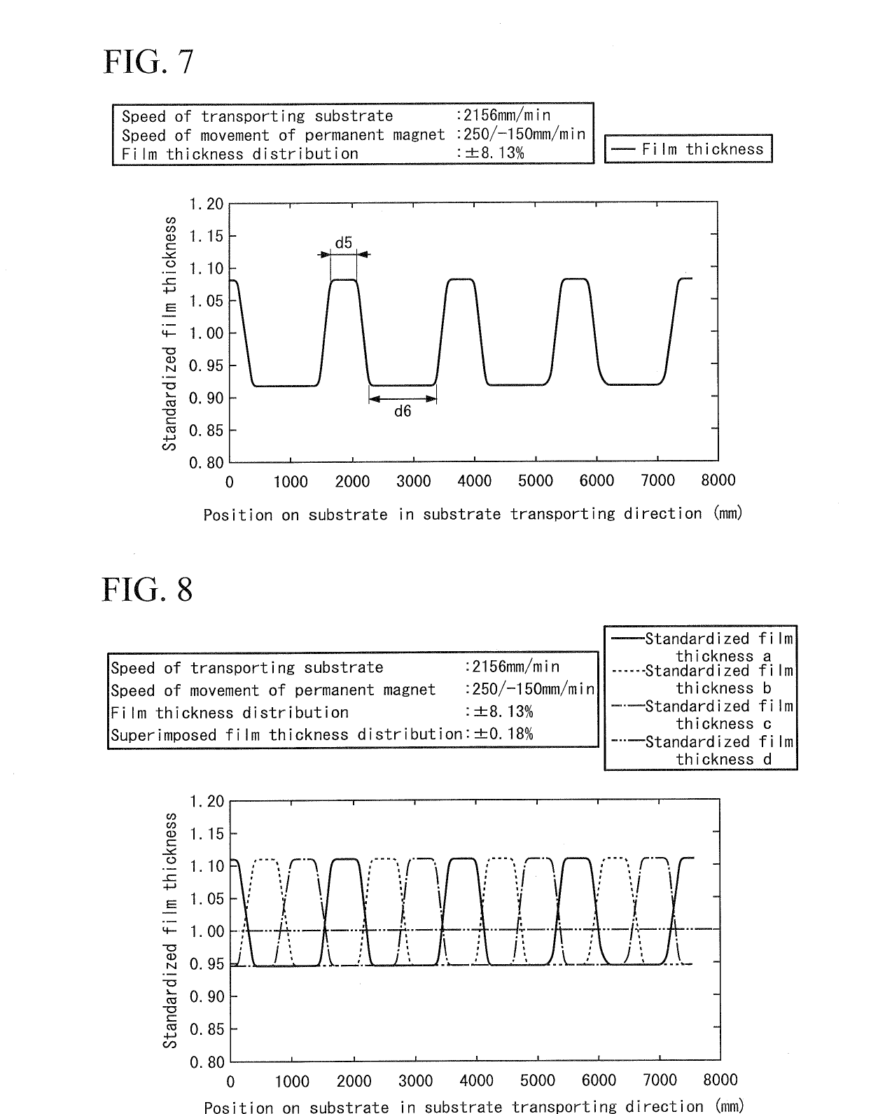

When conducting film formation on the substrate 21 under such conditions, if the film formation is conducted on the substrate 21 by means of sputtering film forming with use of one unit of the magnetron cathode 115, a thin film having a rectangular wave form shape illustrated in FIG. 7 in the thickness direction (film thickness distribution is ±8.13%) is formed on the substrate 21, in the direction of transporting the substrate 21. At this time, the ratio of the width d5 in the substrate transporting direction of the portion having the thickest film thickness, and the width d6 in the substrate transporting direction of the portion having the thinnest film thickness, becomes approximately 1:2.

Therefore, as shown in FIG. 8, by using three units of the magnetron cathodes 115a, 115b, and 115c and adjusting the phases so that the thin film shape to be formed by each of the magnetron cathodes 115a, 115b, and 115c is shifted by a ⅓ cycle, a thin film having a standardized film thickness a is formed on the substrate 21 by the first magnetron cathode 115a, a thin film having a standardized film thickness b is formed on the substrate 21 by the second magnetron cathode 115b, and a thin film having a standardized film thickness c is formed on the substrate 21 by the third magnetron cathode 115c. That is to say, with use of three units of the magnetron cathodes 115a, 115b, and 115c, a thin film having a standardized film thickness d in the thickness direction (superimposed film thickness distribution is ±0.08%) is formed on the substrate 21, and the film thickness can be made substantially uniform.

The standardized film thickness d is an average value (the resultant value of dividing by 3) of the superimposed values of the standardized film thickness a, standardized film thickness b, and standardized film thickness c.

According to the present embodiment, when three units of the magnetron cathode 115 are arranged along the direction of transporting the substrate 21 and each of the magnetron cathodes 115a, 115b, and 115c individually performs film formation, the speed of the reciprocating movement of each of the permanent magnets 29 is adjusted so that the ratio of the width d5 of the portion having the thickest film thickness and the width d6 of the portion having the thinnest film thickness becomes 1:2 in a case where the thin film shape is formed in a rectangular wave form shape. Furthermore, the phase of the reciprocating movement of each of the permanent magnets 29 is adjusted so that the phases of the film thickness variation in the substrate transporting direction of the thin film to be formed on the substrate 21 by the respective magnetron cathodes 115a, 115b, and 115c are respectively shifted by a ⅓ cycle.

Therefore, by superimposing the thin film shape formed on the substrate 21 with the first magnetron cathode 115a, the thin film shape formed with the second magnetron cathode 115b, and the thin film shape formed with the third magnetron cathode 115c, the film thickness of the thin film formed on the substrate 21 can be made substantially uniform along the transporting direction thereof. In the present embodiment, d5:d6=1:2, however, this may be inverted and set to d5:d6=2:1. Also in this case, by superimposing the thin film shapes formed by the respective magnetron cathodes 115a, 115b, and 115c, the film thickness of the thin film formed on the substrate 21 can be made substantially uniform along the transporting direction thereof.

### Third Embodiment

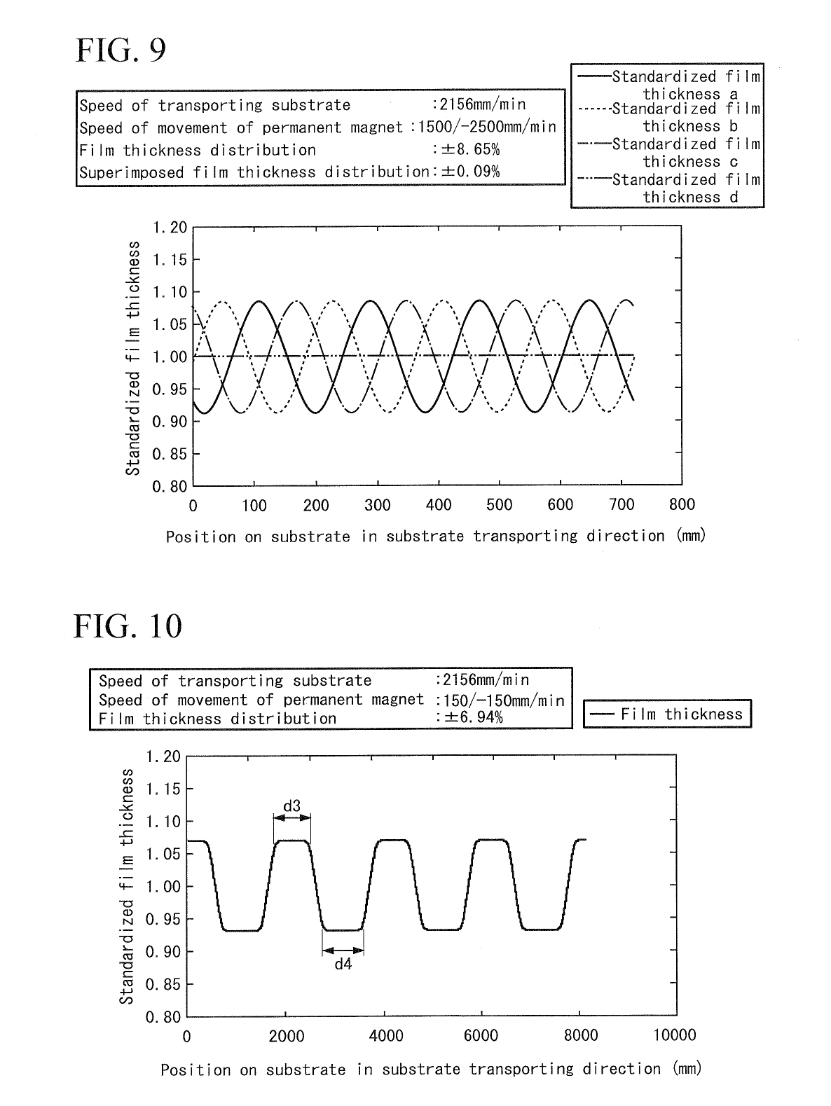

Next, a third embodiment of the present invention is described, with reference to FIG. 4 and FIG. 9.

The present embodiment only differs from the second embodiment in the speed of the movement of the magnetron cathode and the permanent magnets while other configurations thereof are substantially the same as those in the second embodiment, and accordingly the same reference symbols are given to the same portions and detailed descriptions thereof are omitted.

A sputtering film forming apparatus of the present embodiment is substantially the same as that in the second embodiment. A sputtering film forming apparatus 110 has three units of the magnetron cathode 115. The magnetron cathodes 115 are such that one which the substrate 21 passes first is a first magnetron cathode 115a, one which the substrate 21 passes second is a second magnetron cathode 115b, and one which the substrate 21 passes third is a third magnetron cathode 115c.

Here, the speed of transporting the substrate 21 is set at 2156 mm/minute. Moreover, the speed of the movement of the permanent magnet 29 in the same direction as the direction of transporting the substrate 21 is set at 1500 mm/minute, and the speed of the movement thereof in the direction opposite to the direction of transporting the substrate 21 is set at 2500 mm/minute. As a sputtering gas, an Ar gas is introduced into the sputtering chamber 13, and a small amount of oxygen gas is introduced as a reactive gas.

If film formation is conducted on the substrate 21 by means of sputtering film forming with use of one unit of the magnetron cathode 115 under such conditions, a thin film having a sine wave form shape (round wave form) illustrated in FIG. 4 in the thickness direction (film thickness distribution is ±8.65%) is formed on the substrate 21, in the direction of transporting the substrate 21. This sine wave form shape is such that the width d7 in the substrate transporting direction of the portion having a film thickness thicker than the average value, and the width d8 in the substrate transporting direction of the portion having a film thickness thinner than the average value, are substantially the same. That is to say, the film thickness deviation in the substrate transporting direction in a region where the film thickness becomes thicker than the average value, and the film thickness deviation in the substrate transporting direction in a region where the film thickness becomes thinner than the average value, have the same level of amplitude while the polarities thereof are opposite.

Therefore, as shown in FIG. 9, by using three units of the magnetron cathodes 115a, 115b, and 115c and adjusting the phases so that the thin film shape to be formed by each of the magnetron cathodes 115a, 115b, and 115c is shifted by a ⅓ cycle, a thin film having a standardized film thickness a is formed on the substrate 21 by the first magnetron cathode 115a, a thin film having a standardized film thickness b is formed on the substrate 21 by the second magnetron cathode 115b, and a thin film having a standardized film thickness c is formed on the substrate 21 by the third magnetron cathode 115c. That is to say, with use of three units of the magnetron cathodes 115a, 115b, and 115c, a thin film having a standardized film thickness d in the thickness direction (superimposed film thickness distribution is ±0.09%) is formed on the substrate 21, and the film thickness can be made substantially uniform.

According to the present embodiment, when three units of the magnetron cathode 115 are arranged along the direction of transporting the substrate 21 and each of the magnetron cathodes 115a, 115b, and 115c individually performs film formation, the speed of the reciprocating movement of each of the permanent magnets 29 is adjusted so that, in a case where the thin film shape is formed in a sine wave form (round wave form) shape, the film thickness deviation in the substrate transporting direction in a region where the film thickness becomes thicker than the average value, and the film thickness deviation in the substrate transporting direction in a region where the film thickness becomes thinner than the average value, have the same level of amplitude while the polarities thereof are opposite. Furthermore, the phase of the reciprocating movement of each of the permanent magnets 29 is adjusted so that the phases of the film thickness variation in the substrate transporting direction of the thin film to be formed on the substrate 21 by the respective magnetron cathodes 115a, 115b, and 115c are respectively shifted by a ⅓ cycle.

Therefore, by superimposing the thin film shape formed on the substrate 21 with the first magnetron cathode 115a, the thin film shape formed with the second magnetron cathode 115b, and the thin film shape formed with the third magnetron cathode 115c, the film thickness of the thin film formed on the substrate 21 can be made substantially uniform along the transporting direction thereof.

According to the first to third embodiments, in either case of using two units or three units of the magnetron cathode 15 (115), the distribution of the film thickness on the substrate 21 can be made substantially uniform by setting the speed of the movement of the permanent magnet 29 to a predetermined value. In the case of using four or more units of the magnetron cathode 15 (115), the film thickness distribution can be made substantially uniform as described above by combining the two-unit configuration and three-unit configuration mentioned above.

For example, the magnetron cathode 15 may be divided into two-unit+two-unit in the case of using four units, may be divided into two-unit+three-unit in the case of using five units, may be divided into three-unit+three-unit or two-unit+two-unit+two-unit in the case of using six units, and may be divided into two-unit+two-unit+three-unit in the case of using seven units.

The technical scope of the present invention is not to be considered as being limited to the above described embodiments, but may include ones with various modifications that are made to the above embodiments without departing from the scope of the invention. That is to say, the specific shapes, configurations and the like mentioned in the above embodiments are merely examples, and modifications may be appropriately made thereto.

For example, the present embodiments have been described in a case of continuously transporting the substrate, however, they may be applied to a case of intermittently transporting the substrate.

### INDUSTRIAL APPLICABILITY

According to the sputtering film forming method of the present invention, the relative speed between the magnet and the substrate can be adjusted in cases where the magnet is moved in the first direction and where the magnet is moved in the second direction. Accordingly, the thin film shape to be formed on the substrate can be controlled. Therefore, the film thickness can be made uniform at a higher level of precision.

What is claimed is:

1-6. (canceled)

7. A sputtering film forming method, comprising:
arranging a first magnetron cathode with a magnet arranged on a back surface side of a target;
moving a substrate in a first direction on a front surface side of the target; and
performing sputtering film formation on the substrate by moving the magnet in reciprocating motion in the first direction and a second direction which is opposite to the first direction, wherein a speed of the magnet in the first direction and a speed of the magnet in the second direction are different from each other.

8. The sputtering film forming method according to claim 7, further comprising:
arranging a second magnetron cathode and the first magnetron cathode along the first direction and sputtering film formation on the substrate using the respective magnetron cathodes at the same time;
wherein the speed of the movement of the respective magnets in the first direction and the speed of the movement of the respective magnets in the second direction are adjusted so that a film thickness deviation in the first direction in a region where the film thickness becomes thicker than an average value, and the film thickness deviation in the first direction in a region where the film thickness becomes thinner than the average value, have the same level of amplitude while the polarities thereof are opposite;
and wherein a phase of reciprocating movement of the respective magnets is adjusted so that the phase of a film thickness variation in the first direction of a thin film to be formed on the substrate by the respective magnetron cathodes is respectively shifted by a half cycle.

9. The sputtering film forming method according to claim 7, further comprising:
arranging a second and a third magnetron cathode and the first magnetron cathode along the first direction; and
performing sputtering film formation on the substrate individually using the respective magnetron cathodes at the same time so as to form a thin film with a film thickness that changes in a rectangular wave form shape;
wherein the speed of the movement of the respective magnets in the first direction and the speed of the movement of the respective magnets in the second direction are adjusted so that a ratio of a length in the first direction in a portion where the film thickness is the thickest and a length in the first direction in a portion where the film thickness is the thinnest is 1:2 or 2:1,
and wherein a phase of reciprocating movement of the respective magnets is adjusted so that the phase of film thickness variation in the first direction of a thin film to be formed on the substrate by the respective magnetron cathodes is respectively shifted by a ⅓ cycle.

10. The sputtering film forming method according to claim 7, wherein arranging a second and a third magnetron cathode and the first magnetron cathode along the first direction; and
performing sputtering film formation on the substrate individually using the respective magnetron cathodes at the same time so as to form a thin film with a film thickness that changes in a sine wave form shape;
wherein the speed of the movement of the respective magnets in the first direction and the speed of the movement of the respective magnets in the second direction are adjusted so that a film thickness deviation in the first direction in a region where the film thickness becomes thicker than the average value and a film thickness deviation in the first direction in a region where the film thickness becomes thinner than the average value, have the same level of amplitude while the polarities thereof are opposite;
and wherein a phase of reciprocating movement of the respective magnets is adjusted so that the phase of film thickness variation in the first direction of a thin film to be formed on the substrate by the respective magnetron cathodes is respectively shifted by a ⅓ cycle.

11. The sputtering film forming method according to claim 7, further comprising:
arranging at least a second, a third and a fourth magnetron cathode and the first magnetron cathode along the first direction;
dividing the magnetron cathodes into a first aggregate that includes two of the magnetron cathodes and a second aggregate that includes three of the magnetron cathodes;
arranging the first aggregate of magnetron cathodes along the first direction and sputtering film formation on the substrate using the respective magnetron cathodes at the same time;
wherein the speed of the movement of the respective magnets in the first direction and the speed of the movement of the respective magnets in the second direction are adjusted so that a film thickness deviation in the first direction in a region where the film thickness becomes thicker than an average value, and the film thickness deviation in the first direction in a region where the film thickness becomes thinner than the average value, have the same level of amplitude while the polarities thereof are opposite;
and wherein a phase of reciprocating movement of the respective magnets is adjusted so that the phase of a film thickness variation in the first direction of a thin film to be formed on the substrate by the respective magnetron cathodes is respectively shifted by a half cycle.

12. The sputtering film forming method according to claim 7, further comprising:
arranging at least a second, a third and a fourth magnetron cathode and the first magnetron cathode along the first direction;
dividing the magnetron cathodes into a first aggregate that includes two of the magnetron cathodes and a second aggregate that includes three of the magnetron cathodes;
arranging the second aggregate of magnetron cathodes along the first direction and sputtering film formation on the substrate using the respective magnetron cathodes at the same time so as to form a thin film with a film thickness that changes in a rectangular wave form shape;
wherein the speed of the movement of the respective magnets in the first direction and the speed of the movement of the respective magnets in the second direction are adjusted so that a ratio of a length in the first direction in a portion where the film thickness is the thickest and a length in the first direction in a portion where the film thickness is the thinnest is 1:2 or 2:1,
and wherein a phase of reciprocating movement of the respective magnets is adjusted so that the phase of film thickness variation in the first direction of a thin film to be formed on the substrate by the respective magnetron cathodes is respectively shifted by a ⅓ cycle.

13. The sputtering film forming method according to claim 7, further comprising:
arranging at least a second, a third and a fourth magnetron cathode and the first magnetron cathode along the first direction;
dividing the magnetron cathodes into a first aggregate that includes two of the magnetron cathodes and a second aggregate that includes three of the magnetron cathodes;
arranging the second aggregate of magnetron cathodes along the first direction and sputtering film formation on the substrate using the respective magnetron cathodes at the same time so as to form a thin film with a film thickness that changes in a sine wave form shape;
wherein the speed of the movement of the respective magnets in the first direction and the speed of the movement of the respective magnets in the second direction are adjusted so that a film thickness deviation in the first direction in a region where the film thickness becomes thicker than the average value and a film thickness deviation in the first direction in a region where the film thickness becomes thinner than the average value, have the same level of amplitude while the polarities thereof are opposite;
and wherein a phase of reciprocating movement of the respective magnets is adjusted so that the phase of film thickness variation in the first direction of a thin film to be formed on the substrate by the respective magnetron cathodes is respectively shifted by a ⅓ cycle.

14. A sputtering film forming apparatus, comprising:
a target arranged within a sputtering chamber;
a magnet arranged on a back surface side of this target;
wherein the sputtering chamber is configured to move a substrate in a first direction on a front surface side of the target, and the magnet is configured to move in reciprocating motion in the first direction and a second direction which is opposite to the first direction;
and wherein a speed of the movement of the magnet in the first direction and a speed of the movement of the magnet in the second direction are set at different speeds.
